(19) United States
(12) Patent Application Publication
(10) Pub. No.: US 2025/0089570 A1
(43) Pub. Date: Mar. 13, 2025

(54) METHOD FOR MANUFACTURING VIBRATION POWER GENERATION DEVICE

(71) Applicant: SEIKO EPSON CORPORATION, Tokyo (JP)

(72) Inventors: Takashi Miyata, Shiojiri-shi (JP); Yukio Yamauchi, Chino-shi (JP)

(21) Appl. No.: 18/826,618

(22) Filed: Sep. 6, 2024

(30) Foreign Application Priority Data
Sep. 7, 2023 (JP) 2023-145329

(51) Int. Cl. H10N 30/01

(52) U.S. Cl. CPC H10N 30/01

(57) ABSTRACT

A method for manufacturing a vibration power generation device includes: patterning a first silicon layer to form a first comb electrode and a second comb electrode; supplying an alkali ion solution to a surface of the first comb electrode and a surface of the second comb electrode in a state in which a voltage is applied between the first comb electrode and the second comb electrode in such a way that the first comb electrode has a higher potential than the second comb electrode; drying the alkali ion solution; forming a first oxide film on the surface of the first comb electrode and forming a second oxide film on the surface of the second comb electrode by heating the first silicon layer; and a applying a voltage to the second comb electrode to charge the second oxide film.

The present application is based on, and claims priority from JP Application Serial Number 2023-145329, filed Sep. 7, 2023, the disclosure of which is hereby incorporated by reference herein in its entirety.

### BACKGROUND

### 1. Technical Field

The present disclosure relates to a method for manufacturing a vibration power generation device.

### 2. Related Art

JP-A-2023-091647 describes a vibration power generation element formed by patterning a silicon on insulator (SOI) substrate by a semiconductor process. The SOI substrate is a substrate formed by inserting a silicon oxide layer as a BOX layer between a first silicon layer as a handle layer and a second silicon layer as a device layer. The vibration power generation element includes a support portion, a spring portion coupled to the support portion, a movable portion coupled to the support portion via the spring portion, a movable electrode coupled to the movable portion, and a fixed electrode coupled to the support portion. A negatively charged electret film is formed on the movable electrode. In such a vibration power generation element, the movable portion vibrates while elastically deforming the spring portion when an external force is applied, and such vibration changes a capacitance between the movable electrode and the fixed electrode, thereby generating power.

However, in the above-described vibration power generation element, both the movable electrode and the fixed electrode are formed from the second silicon layer. Therefore, it is necessary to selectively form the electret film only on the movable electrode in a state in which the movable electrode and the fixed electrode mesh with a narrow pitch after patterning the movable electrode and the fixed electrode by the semiconductor process. Therefore, there is a problem that it is difficult to form the electret film.

### SUMMARY

According to an aspect of the present disclosure, a method for manufacturing a vibration power generation device includes: a first silicon layer patterning step of patterning a first silicon layer to form a first comb electrode and a second comb electrode aligned with the first comb electrode; an alkali ion solution supply step of supplying an alkali ion solution to a surface of the first comb electrode and a surface of the second comb electrode in a state in which a voltage is applied between the first comb electrode and the second comb electrode in such a way that the first comb electrode has a higher potential than the second comb electrode; a drying step of drying the alkali ion solution; an oxide film formation step of forming a first oxide film on the surface of the first comb electrode and forming a second oxide film on the surface of the second comb electrode by heating the first silicon layer; and a charging step of applying a voltage to the second comb electrode to charge the second oxide film, thereby forming an electret film.

### BRIEF DESCRIPTION OF THE DRAWINGS

FIG. 1 is a plan view of a vibration power generation device according to an exemplary embodiment.

FIG. 2 is a plan view of the vibration power generation device of FIG. 1 after a first silicon layer is removed.

FIG. 3 is a cross-sectional view taken along line III-III in FIG. 1.

FIG. 4 is a flowchart illustrating a process of manufacturing the vibration power generation device.

FIG. 5 is a cross-sectional view for describing a method for manufacturing the vibration power generation device.

FIG. 6 is a cross-sectional view for describing the method for manufacturing the vibration power generation device.

FIG. 7 is a cross-sectional view for describing the method for manufacturing the vibration power generation device.

FIG. 8 is a cross-sectional view for describing the method for manufacturing the vibration power generation device.

FIG. 9 is a cross-sectional view for describing the method for manufacturing the vibration power generation device.

FIG. 10 is a cross-sectional view for describing the method for manufacturing the vibration power generation device.

FIG. 11 is a cross-sectional view for describing the method for manufacturing the vibration power generation device.

FIG. 12 is a cross-sectional view for describing the method for manufacturing the vibration power generation device.

FIG. 13 is a cross-sectional view for describing the method for manufacturing the vibration power generation device.

FIG. 14 is a cross-sectional view for describing the method for manufacturing the vibration power generation device.

FIG. 15 is a cross-sectional view for describing the method for manufacturing the vibration power generation device.

FIG. 16 is a cross-sectional view for describing the method for manufacturing the vibration power generation device.

FIG. 17 is a cross-sectional view for describing the method for manufacturing the vibration power generation device.

FIG. 18 is a cross-sectional view for describing the method for manufacturing the vibration power generation device.

FIG. 19 is a cross-sectional view for describing the method for manufacturing the vibration power generation device.

FIG. 20 is a cross-sectional view for describing the method for manufacturing the vibration power generation device.

### DESCRIPTION OF EMBODIMENTS

Hereinafter, a method for manufacturing a vibration power generation device of the present disclosure will be described in detail based on embodiments illustrated in the accompanying drawings.

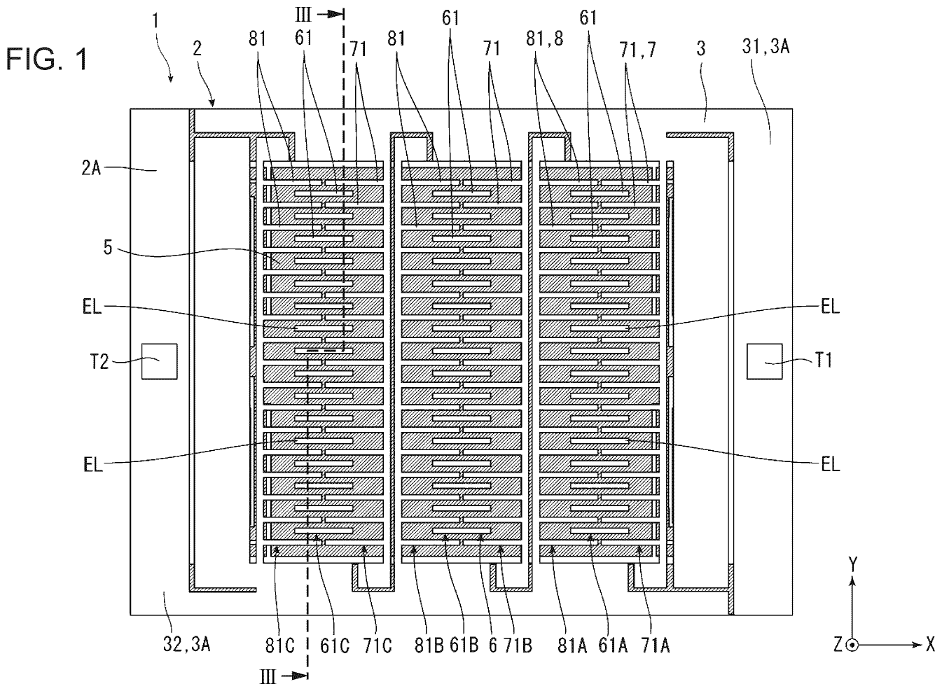

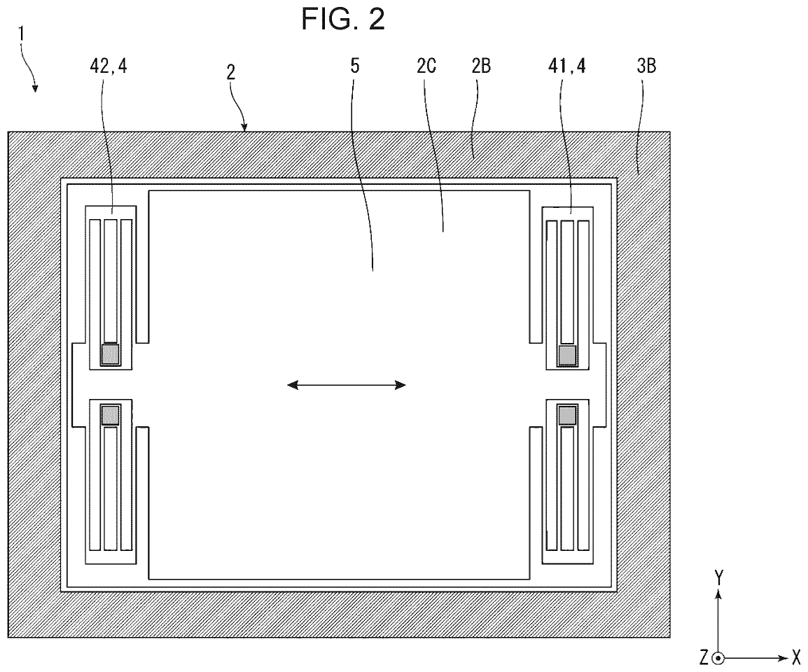

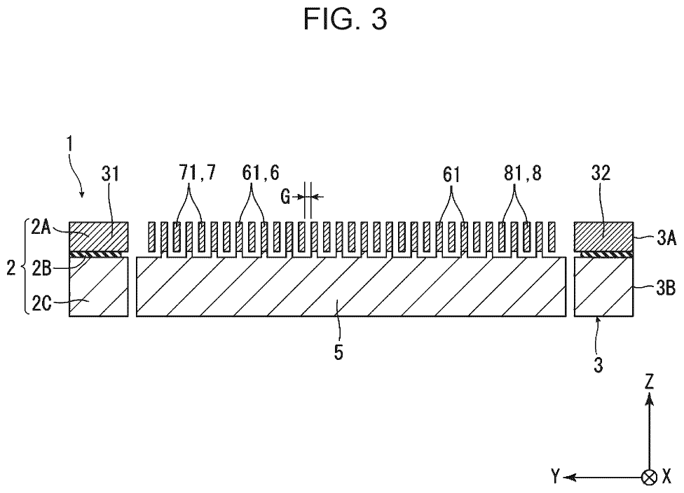

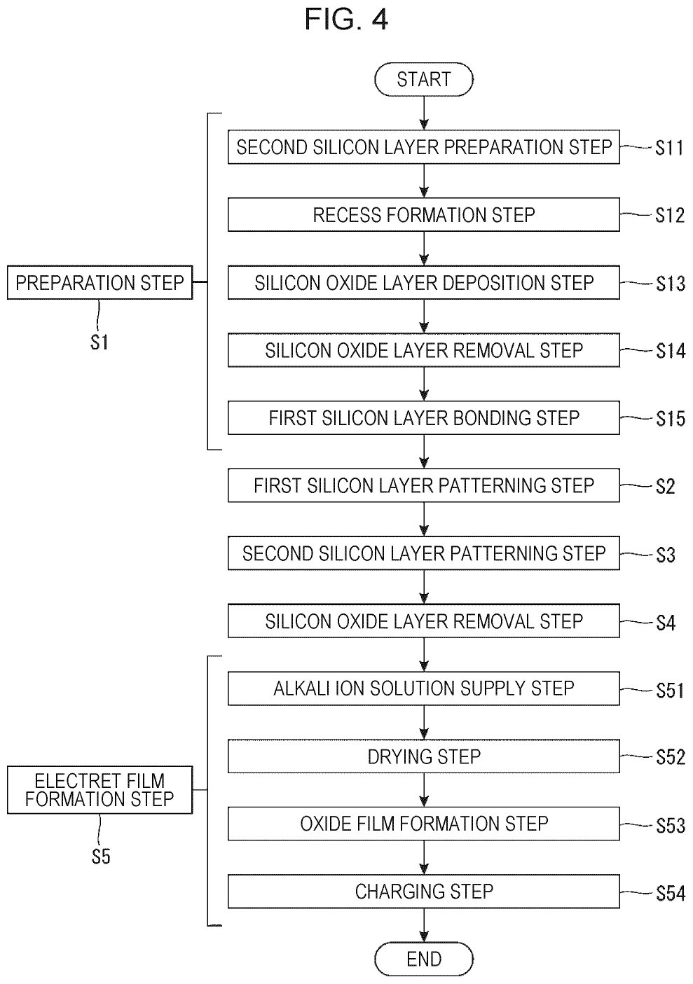

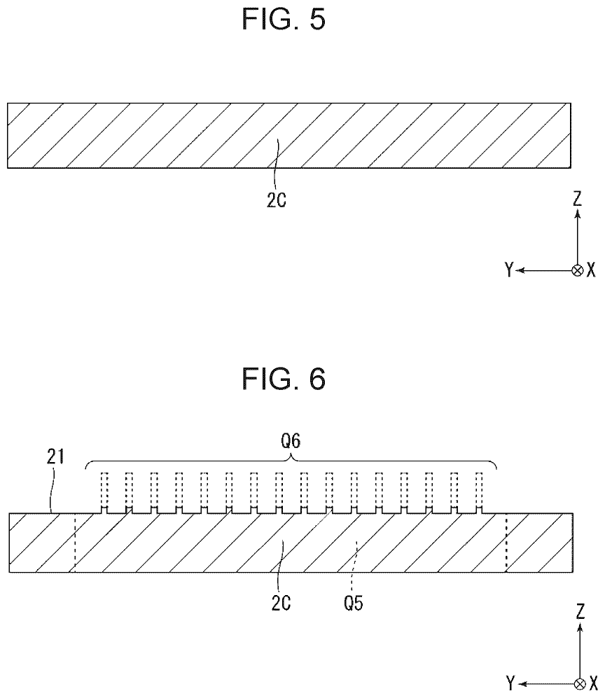

FIG. 1 is a plan view of the vibration power generation device according to an exemplary embodiment. FIG. 2 is a plan view of the vibration power generation device of FIG. 1 after a first silicon layer is removed. FIG. 3 is a cross-sectional view taken along line III-III in FIG. 1. FIG. 4 is a flowchart illustrating a process of manufacturing the vibration power generation device. FIGS. 5 to 20 are cross-sectional views for describing a method for manufacturing the vibration power generation device.

In the drawing except for FIG. 4, three mutually orthogonal axes, an X axis, a Y axis, and a Z axis, are illustrated. A direction along the X axis, that is, a direction parallel to the X axis, is referred to as an “X-axis direction”, a direction along the Y axis is referred to as a “Y-axis direction”, and a direction along the Z axis is referred to as a “Z-axis direction”. A side indicated by a tip of an arrow on each axis is also referred to as a “positive side”, and a side opposite thereto is also referred to as a “negative side”. The positive side in the Z-axis direction is also referred to as an “upper side”, and the negative side in the Z-axis direction is also referred to as a “lower side”.

A vibration power generation device 1 illustrated in FIGS. 1 and 2 is an electrostatic induction type vibration power generation device that is driven by an external force to generate power. Such a vibration power generation device 1 is manufactured by patterning a silicon on insulator (SOI) substrate 2 using a semiconductor process.

As illustrated in FIG. 3, the SOI substrate 2 is a substrate in which a silicon oxide layer 2B is interposed between a first silicon layer 2A and a second silicon layer 2C. The first silicon layer 2A is also referred to as a device layer, the second silicon layer 2C is also referred to as a handle layer, and the silicon oxide layer 2B is also referred to as a BOX layer. A thickness of the first silicon layer 2A is approximately 200 μm or more and 300 μm or less, a thickness of the silicon oxide layer 2B is approximately 20 μm, and a thickness of the second silicon layer 2C is approximately 200 μm or more and 500 μm or less. However, there are no particular limitations on the thickness of each of these components.

As illustrated in FIGS. 1 and 2, the vibration power generation device 1 includes a support portion 3, a movable portion 5 that is movable relative to the support portion 3, a spring portion 4 coupling the support portion 3 and the movable portion 5 to each other, a movable electrode 6 which is a second comb electrode coupled to the movable portion 5, and first and second fixed electrodes 7 and 8 which are first comb electrodes coupled to the support portion 3. The movable portion 5 is displaceable in the X-axis direction which is a first direction relative to the support portion 3 while elastically deforming the spring portion 4. In the vibration power generation device 1 having such a configuration, the movable portion 5 vibrates in the X-axis direction while elastically deforming the spring portion 4 when an external force is applied in the X-axis direction, and such vibration changes a capacitance between the movable electrode 6 and the first and second fixed electrodes 7 and 8, thereby generating power.

### Support Portion 3

As illustrated in FIG. 3, the support portion 3 is formed from a stacked body of the first silicon layer 2A, the silicon oxide layer 2B, and the second silicon layer 2C, and has a frame shape in plan view when viewed from the Z-axis direction. The other components are arranged on an inner side of the support portion 3.

As illustrated in FIG. 3, the support portion 3 includes a first support portion 3A formed from the first silicon layer 2A and a second support portion 3B formed from the second silicon layer 2C, and the first support portion 3A and the second support portion 3B are stacked with the silicon oxide layer 2B interposed therebetween. As illustrated in FIG. 2, the second support portion 3B positioned in the lowermost layer has a frame shape in plan view when viewed from the Z-axis direction. On the other hand, as illustrated in FIG. 1, the first support portion 3A positioned in the uppermost layer is divided into a first fixed electrode support portion 31 to which the first fixed electrode 7 is coupled, and a second fixed electrode support portion 32 to which the second fixed electrode 8 is coupled. In other words, the first fixed electrode support portion 31 and the second fixed electrode support portion 32 are separately supported by the second support portion 3B, and the first fixed electrode support portion 31, the second fixed electrode support portion 32, and the second support portion 3B are integrated to form the support portion 3. The first fixed electrode support portion 31 and the second fixed electrode support portion 32 are insulated from each other by the silicon oxide layer 2B. The insulation between the first fixed electrode support portion 31 and the second fixed electrode support portion 32 may also be achieved by forming patterns of the first fixed electrode support portion 31 and the second fixed electrode support portion 32 in plan view in such a way that the first fixed electrode support portion 31 and the second fixed electrode support portion 32 are spaced apart from each other.

As illustrated in FIG. 1, an electrode pad T1 electrically coupled to the first fixed electrode 7 is disposed on the first fixed electrode support portion 31, and an electrode pad T2 electrically coupled to the second fixed electrode 8 is disposed on the second fixed electrode support portion 32.

### Movable Portion 5

As illustrated in FIG. 2, the movable portion 5 is formed from the second silicon layer 2C, and is positioned at a central portion of the vibration power generation device 1 in plan view when viewed from the Z-axis direction.

### Spring Portion 4

As illustrated in FIG. 2, the spring portion 4 is formed from the second silicon layer 2C. In other words, the spring portion 4 is formed from the same layer as that of the movable portion 5. Therefore, the spring portion 4 can be disposed near the center of gravity of the movable portion 5, and unnecessary displacement of the movable portion 5, that is, displacement in directions other than the X-axis direction, which is a vibration direction, can be suppressed. Therefore, efficient power generation can be performed. The spring portion 4 includes a first spring portion 41 and a second spring portion 42 that are elastically deformed in the X-axis direction. The first spring portion 41 is positioned on a positive side of the movable portion 5 in the X-axis direction, and couples an end portion of the movable portion 5 on the positive side in the X-axis direction to the support portion 3. On the other hand, the second spring portion 42 is positioned on a negative side of the movable portion 5 in the X-axis direction, and couples an end portion of the movable portion 5 on the negative side in the X-axis direction to the support portion 3. In this way, the movable portion 5 is supported from both sides in the X-axis direction by the first and second spring portions 41 and 42, so that the movable portion 5 can stably vibrate in the X-axis direction.

In the present embodiment, the first and second spring portions 41 and 42 are coupled to the first support portion 3A, but are not limited thereto, and the first and second spring portions 41 and 42 may be coupled to the second support portion 3B.

### Movable Electrode 6

As illustrated in FIG. 1, the movable electrode 6 is formed from the first silicon layer 2A. The movable electrode 6 overlaps the movable portion 5 in plan view when viewed from the Z-axis direction. As illustrated in FIG. 3, the movable electrode 6 is coupled to the movable portion 5 and protrudes from an upper surface of the movable portion 5 toward the positive side in the Z-axis direction. As the movable electrode 6 and the movable portion 5 overlap each other in the Z-axis direction as described above, the movable portion 5 can be increased in size and a mass thereof can be increased without increasing dimensions of the vibration power generation device 1 in plan view. As a result, sensitivity of the vibration power generation device 1 can be improved, so that the movable portion 5 can efficiently vibrate even in a low frequency band. Furthermore, the movable electrode 6 and the first and second fixed electrodes 7 and 8 can be formed over a wide range regardless of the size of the movable portion 5, and thus, the capacitance between the movable electrode 6 and the first and second fixed electrodes 7 and 8 can be increased. As a result, it is possible to increase a power generation amount of the vibration power generation device 1.

Here, as illustrated in FIG. 3, the silicon oxide layer 2B is not formed between the movable electrode 6 and the movable portion 5, and the first silicon layer 2A and the second silicon layer 2C are in contact with each other. Therefore, the movable electrode 6 is electrically coupled to the movable portion 5. With such a configuration, a charging step S54 described below can be easily performed.

As illustrated in FIG. 1, the movable electrode 6 includes a plurality of movable electrode fingers 61 extending in the X-axis direction. The plurality of movable electrode fingers 61 are arranged in a matrix in the X-axis direction and the Y-axis direction. In the illustrated configuration, three rows in which the plurality of movable electrode fingers 61 are aligned in a comb-like shape in the Y-axis direction are arranged in the X-axis direction. In the following description, for ease of explanation, a row on the positive side in the X-axis direction among the three rows is also referred to as a movable electrode finger group 61A, a row on the negative side in the X-axis direction is also referred to as a movable electrode finger group 61C, and a row at the center is also referred to as a movable electrode finger group 61B. However, the number and arrangement of movable electrode fingers 61 are not particularly limited.

Furthermore, an electret film EL is formed on a surface of each movable electrode finger 61, particularly on a side surface that faces a first or second fixed electrode finger 71 or 81 described below. The electret film EL is a negatively charged film. The electret film EL may be formed on each of the first and second fixed electrode fingers 71 and 81. In this case, contrary to the present embodiment, the movable electrode 6 becomes the first comb electrode, and the first and second fixed electrodes 7 and 8 become the second comb electrodes. However, the electret film EL may be formed on the movable electrode finger 61 as in the present embodiment. By forming the electret film EL on the movable electrode finger 61 that is displaced relative to the support portion 3, an electric charge generated during power generation can be taken out from the first and second fixed electrode fingers 71 and 81 that are fixed to the support portion 3. Therefore, it is easy to take out the electric charge.

### First and Second Fixed Electrodes 7 and 8

As illustrated in FIG. 1, the first fixed electrode 7 and the second fixed electrode 8 are each formed from the first silicon layer 2A. The first fixed electrode 7 and the second fixed electrode 8 overlap the movable portion 5 in plan view when viewed from the Z-axis direction. As illustrated in FIG. 3, the silicon oxide layer 2B between the first and second fixed electrodes 7 and 8 and the movable portion 5 is removed, and a gap of approximately the thickness of the silicon oxide layer 2B is formed between the first and second fixed electrodes 7 and 8 and the movable portion 5. Therefore, contact between the movable portion 5 and the first and second fixed electrodes 7 and 8 is prevented, that is, short circuit between the movable electrode 6 and the first and second fixed electrodes 7 and 8 via the movable portion 5 is prevented.

As illustrated in FIG. 1, the first fixed electrode 7 extends in the X-axis direction and includes the plurality of first fixed electrode fingers 71 arranged in parallel with the movable electrode fingers 61 in the Y-axis direction. In other words, the first fixed electrode 7 extends in the X-axis direction and includes the plurality of first fixed electrode fingers 71 arranged at positions facing the movable electrode fingers 61. Specifically, the first fixed electrode 7 includes a comb-like first fixed electrode finger group 71A including a plurality of first fixed electrode fingers 71 that mesh with the movable electrode finger group 61A from the positive side in the X-axis direction, a comb-like first fixed electrode finger group 71B including a plurality of first fixed electrode fingers 71 that mesh with the movable electrode finger group 61B from the positive side in the X-axis direction, and a comb-like first fixed electrode finger group 71C including a plurality of first fixed electrode fingers 71 that mesh with the movable electrode finger group 61C from the positive side in the X-axis direction. The movable electrode fingers 61 and the first fixed electrode fingers 71 face each other with a predetermined meshing length in the X-axis direction and a gap G in the Y-axis direction in a stationary state.

As illustrated in FIG. 1, the second fixed electrode 8 extends in the X-axis direction and includes the plurality of second fixed electrode fingers 81 arranged in parallel with the movable electrode fingers 61 in the Y-axis direction. Specifically, the second fixed electrode 8 includes a comb-like second fixed electrode finger group 81A including the plurality of second fixed electrode fingers 81 that mesh with the movable electrode finger group 61A from the negative side in the X-axis direction, a comb-like second fixed electrode finger group 81B including the plurality of second fixed electrode fingers 81 that mesh with the movable electrode finger group 61B from the negative side in the X-axis direction, and a comb-like second fixed electrode finger group 81C including the plurality of second fixed electrode fingers 81 that mesh with the movable electrode finger group 61C from the negative side in the X-axis direction. The movable electrode fingers 61 and the second fixed electrode fingers 81 face each other with a predetermined meshing length in the X-axis direction and the gap G in the Y-axis direction in a stationary state.

Hereinabove, the configuration of the vibration power generation device 1 has been briefly described. In the vibration power generation device 1 having such a configuration, the movable portion 5 vibrates in the X-axis direction while elastically deforming the first and second spring portions 41 and 42 when a force is applied in the X-axis direction. The vibration of the movable portion 5 changes the meshing lengths between the movable electrode finger 61 and the first and second fixed electrode fingers 71 and 81 in opposite phases, thereby generating power. Specifically, when the movable portion 5 is displaced toward the positive side in the X-axis direction, a positive electric charge is applied at the first fixed electrode fingers 71 as the meshing length between the first fixed electrode fingers 71 and the movable electrode fingers 61 increases, and an electric charge is discharged at the second fixed electrode fingers 81 as the meshing length between the second fixed electrode fingers 81 and the movable electrode fingers 61 decreases. Conversely, when the movable portion 5 is displaced toward the negative side in the X-axis direction, the applied electric charge is discharged at the first fixed electrode fingers 71 as the meshing length between the first fixed electrode fingers 71 and the movable electrode fingers 61 decreases, and a positive electric charge is applied at the second fixed electrode fingers 81 as the meshing length between the second fixed electrode fingers 81 and the movable electrode fingers 61 increases. In this way, the charge and discharge of the electric charge between the first and second fixed electrode fingers 71 and 81 are repeated in opposite phases.

As the charge and discharge of the electric charge at the first and second fixed electrode fingers 71 and 81 are repeated, a current flows from the vibration power generation device 1 to a rectifier circuit (not illustrated). The current is rectified by the rectifier circuit and input to a secondary battery. As a result, power generated by the vibration power generation device 1 is stored in the secondary battery. The power stored in the secondary battery is supplied to a load as needed. The secondary battery is a rechargeable and dischargeable battery such as a lithium secondary battery. The load is, for example, a circuit for implementing functions of a portable electrical device, and operates by consuming power supplied from the secondary battery. For example, when the portable electrical device is a wristwatch, the load includes a timing circuit or the like and performs various controls such as keeping the current time.

Next, a method for manufacturing the vibration power generation device 1 will be described. As illustrated in FIG. 4, the method for manufacturing the vibration power generation device 1 includes a preparation step S1 of preparing the SOI substrate 2, a first silicon layer patterning step S2 of patterning the first silicon layer 2A to form the first support portion 3A, the movable electrode 6, and the first and second fixed electrodes 7 and 8 in the first silicon layer 2A, a second silicon layer patterning step S3 of patterning the second silicon layer 2C to form the second support portion 3B, the spring portion 4, and the movable portion 5 on the second silicon layer 2C, a silicon oxide layer removal step S4 of removing a part of the silicon oxide layer 2B to separate a movable part, and an electret film formation step S5 of forming the electret film EL on the movable electrode 6.

### Preparation Step S1

The preparation step S1 is a step of preparing the SOI substrate 2 in which the silicon oxide layer 2B is interposed between the first silicon layer 2A and the second silicon layer 2C. In the step S1, as illustrated in FIG. 9, the SOI substrate 2, in which the silicon oxide layer 2B is removed from between a movable electrode formation region Q6 as a second comb electrode formation region in which the movable electrode 6 of the first silicon layer 2A is formed, and a movable portion formation region Q5 in which the movable portion 5 of the second silicon layer 2C is formed, is prepared. As a result, the silicon oxide layer 2B is not interposed between the movable electrode 6 and the movable portion 5, and thus, the movable electrode 6 and the movable portion 5 are structurally electrically coupled.

As illustrated in FIG. 4, the step S1 includes a second silicon layer preparation step S11 of preparing the second silicon layer 2C, a recess formation step S12 of forming a recess 21 on an upper surface of the second silicon layer 2C, a silicon oxide layer deposition step S13 of depositing the silicon oxide layer 2B on the upper surface of the second silicon layer 2C, a silicon oxide layer removal step S14 of removing the silicon oxide layer 2B while leaving a part filled in the recess 21 to expose the upper surface of the second silicon layer 2C, and a first silicon layer bonding step S15 of bonding the first silicon layer 2A to the upper surface of the second silicon layer 2C.

### Second Silicon Layer Preparation Step S11

First, the second silicon layer 2C is prepared as illustrated in FIG. 5. The second silicon layer 2C is, for example, a silicon substrate having a thickness of about 200 μm or more and 500 μm or less.

### Recess Formation Step S12

Next, as illustrated in FIG. 6, the recess 21 is formed on the upper surface of the second silicon layer 2C. The recess 21 is formed in a part excluding a region where the movable electrode formation region Q6 and the movable portion formation region Q5 overlap each other. The method for forming the recess 21 is not particularly limited, and for example, reactive ion etching (RIE) can be used. A thickness of the recess 21 is, for example, about 20 μm.

### Silicon Oxide Layer Deposition Step S13

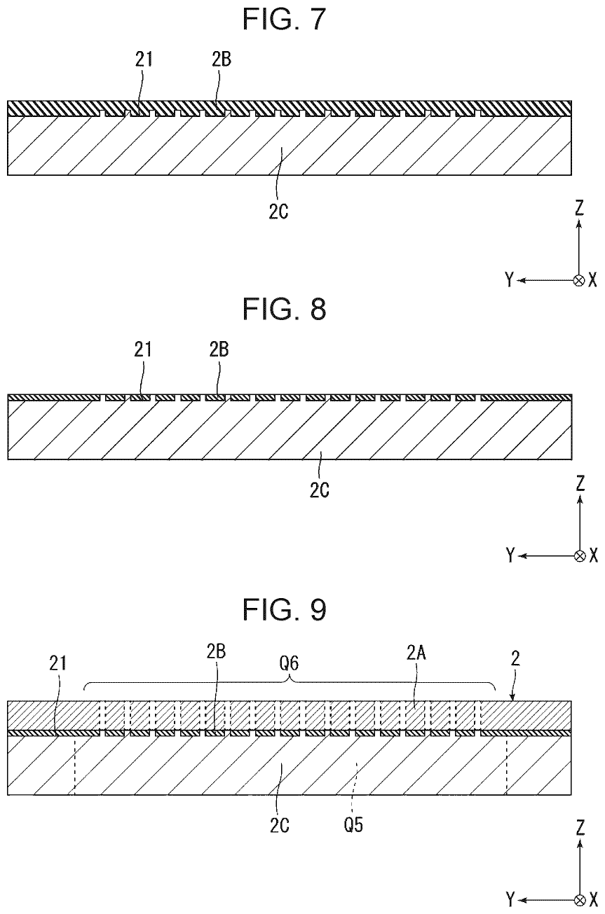

Next, as illustrated in FIG. 7, the silicon oxide layer 2B is formed on the upper surface of the second silicon layer 2C. The deposition method is not particularly limited, and for example, thermal oxidation and plasma chemical vapor deposition (CVD) using tetraethoxysilane (TEOS), SiH₄, or the like as raw material gas can be used.

### Silicon Oxide Layer Removal Step S14

Next, as illustrated in FIG. 8, the silicon oxide layer 2B is removed while leaving the part filled in the recess 21 to expose the upper surface of the second silicon layer 2C. The method for removing the silicon oxide layer 2B is not particularly limited, and for example, chemical mechanical polishing (CMP) can be used.

### First Silicon Layer Bonding Step S15

Next, the first silicon layer 2A is prepared. The first silicon layer 2A is, for example, a silicon substrate with a thickness of about 200 μm or more and 300 μm or less. Next, as illustrated in FIG. 9, the first silicon layer 2A is bonded to the upper surface of the second silicon layer 2C.

The SOI substrate 2 is obtained by performing the above-described steps. According to such a method, the SOI substrate 2 can be easily manufactured. However, the method for manufacturing the SOI substrate 2 is not particularly limited.

### First Silicon Layer Patterning Step S2

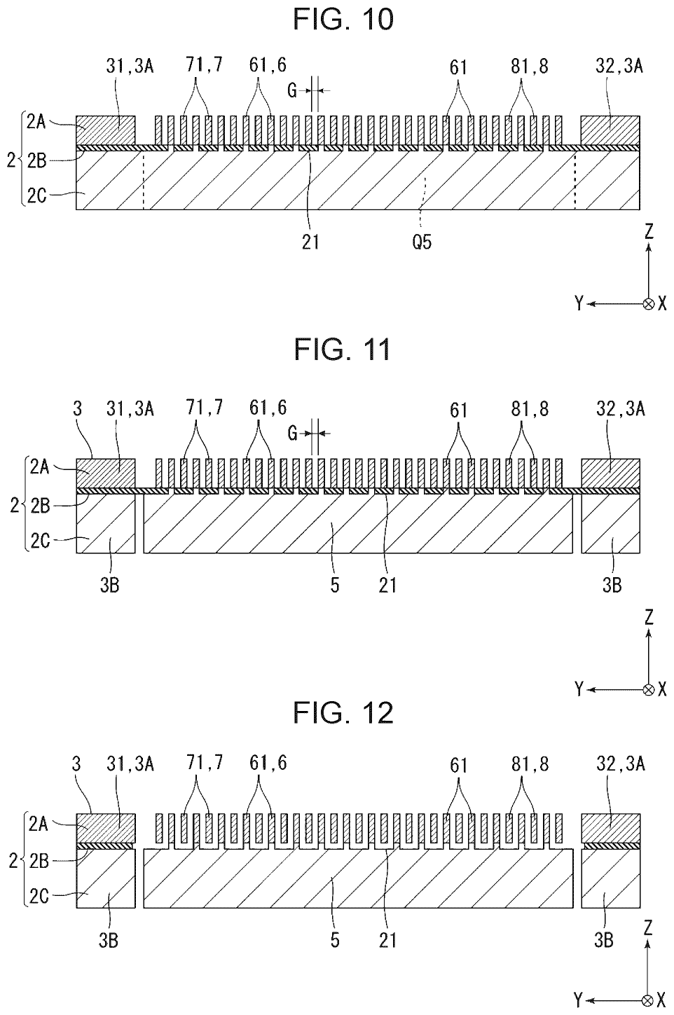

In the first silicon layer patterning step S2, the first silicon layer 2A is patterned by etching to form the first support portion 3A, the movable electrode 6, and the first and second fixed electrodes 7 and 8 in the first silicon layer 2A. Specifically, as illustrated in FIG. 10, the first silicon layer 2A is etched from an upper surface side to form through-holes penetrating through the first silicon layer 2A, thereby forming the first support portion 3A, the movable electrode 6, and the first and second fixed electrodes 7 and 8 in the first silicon layer 2A. At this time, the silicon oxide layer 2B functions as an etching stop layer.

For example, dry etching, particularly reactive ion etching (RIE), can be used for the etching. The through-hole with a high aspect ratio can be formed with high precision by using dry etching, so that the gap G between the movable electrode finger 61 and the first and second fixed electrode fingers 71 and 81 can be designed to be smaller. Therefore, it is possible to manufacture the vibration power generation device 1 having an excellent power generation characteristic. However, the etching method is not particularly limited, and may be, for example, wet etching.

### Second Silicon Layer Patterning Step S3

In the second silicon layer patterning step S3, the second silicon layer 2C is patterned by etching to form the second support portion 3B, the spring portion 4, and the movable portion 5 in the second silicon layer 2C. Specifically, as illustrated in FIG. 11, the second silicon layer 2C is etched from a lower surface side to form through-holes penetrating through the second silicon layer 2C, thereby forming the second support portion 3B, the spring portion 4, and the movable portion 5 in the second silicon layer 2C. At this time, the silicon oxide layer 2B functions as an etching stop layer.

For example, dry etching, particularly reactive ion etching (RIE), can be used for the etching. The through-hole with a high aspect ratio can be formed with high precision by using dry etching. Therefore, a distance between the movable electrode 6 and the first and second fixed electrodes 7 and 8 can be reduced, and the capacitance between the movable electrode 6 and the first and second fixed electrodes 7 and 8 can be increased accordingly. Therefore, it is possible to increase the power generation amount of the vibration power generation device 1. However, the etching method is not particularly limited, and may be, for example, wet etching.

The second silicon layer patterning step S3 may be performed before the first silicon layer patterning step S2, or may be performed simultaneously with the first silicon layer patterning step S2.

### Silicon Oxide Layer Removal Step S4

In the silicon oxide layer removal step S4, as illustrated in FIG. 12, the silicon oxide layer 2B is removed from all parts except for the support portion 3, and the spring portion 4 and the movable portion 5 become movable relative to the support portion 3. However, the part from which the silicon oxide layer 2B is removed is not particularly limited as long as the spring portion 4 and the movable portion 5 can become movable relative to the support portion 3.

An outer shape of the vibration power generation device 1 is formed as described above. By patterning a single SOI substrate 2 to form the outer shape of the vibration power generation device 1 in this way, it is possible to achieve excellent dimensional accuracy and reduce the size of the gap between the movable electrode finger 61 and the first and second fixed electrode fingers 71 and 81. Therefore, it is possible to increase the capacitance between the movable electrode 6 and the first and second fixed electrodes 7 and 8.

### Electret Film Formation Step S5

In the electret film formation step S5, the electret film EL is formed on the movable electrode 6. As illustrated in FIG. 4, the electret film formation step S5 includes an alkali ion solution supply step S51 of supplying an alkali ion solution L to the movable electrode 6 and the first and second fixed electrodes 7 and 8, a drying step S52 of drying the alkali ion solution L adhering to the movable electrode 6 and the first and second fixed electrodes 7 and 8, an oxide film formation step S53 of forming a second oxide film 9B on the movable electrode 6 and forming first oxide films 9A on the first and second fixed electrodes 7 and 8 by heating the first silicon layer 2A, and a charging step S54 of applying a voltage to the movable electrode 6 to charge the second oxide film 9B.

### Alkali Ion Solution Supply Step S51

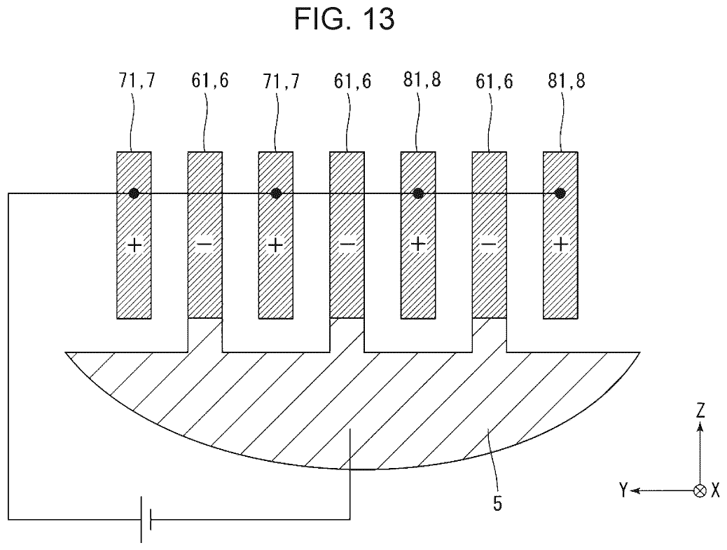

In the alkali ion solution supply step S51, as illustrated in FIG. 13, first, a voltage is applied between the movable electrode 6 and the first and second fixed electrodes 7 and 8 in such a way that the first and second fixed electrodes 7 and 8 have a higher potential than the movable electrode 6. That is, a voltage is applied between the movable electrode 6 and the first and second fixed electrodes 7 and 8 in such a way that the first and second fixed electrodes 7 and 8 become positive electrodes and the movable electrode 6 becomes a negative electrode.

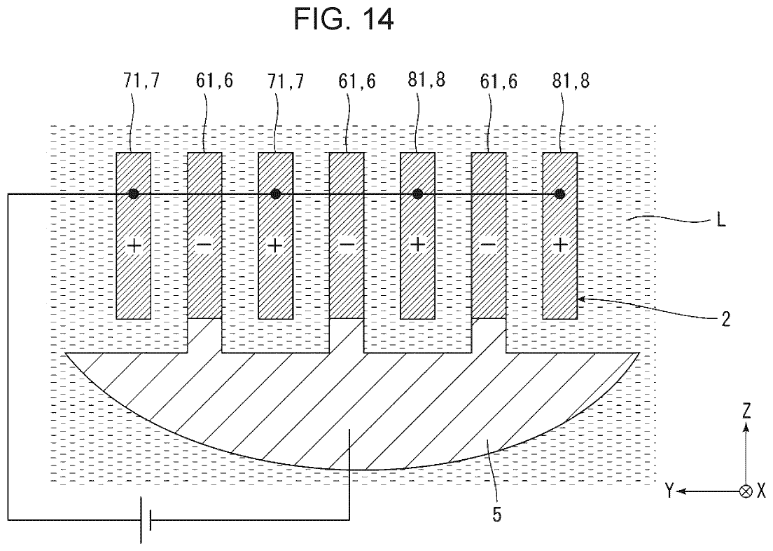

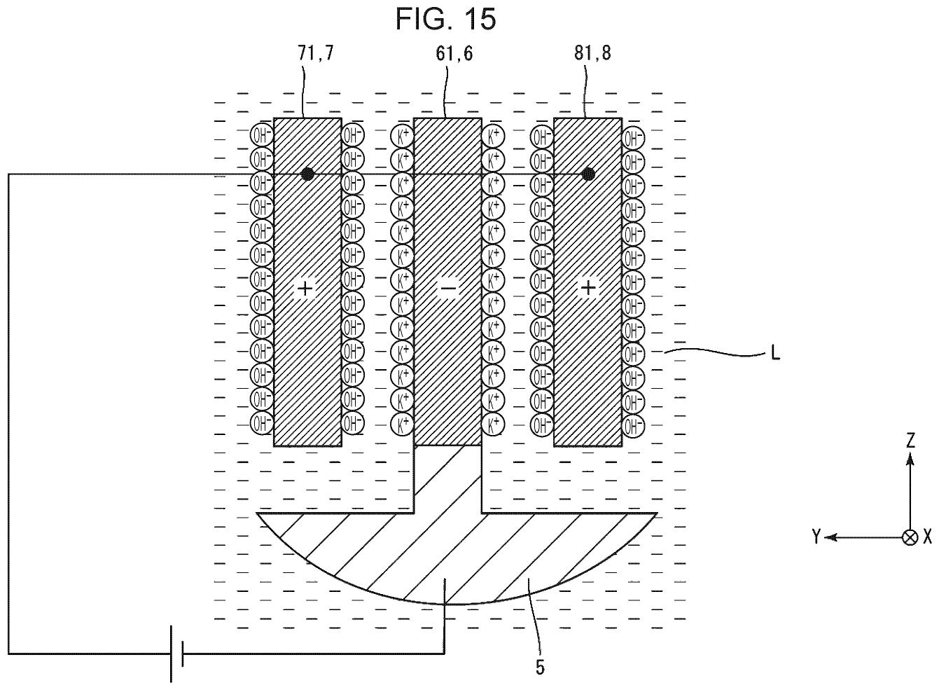

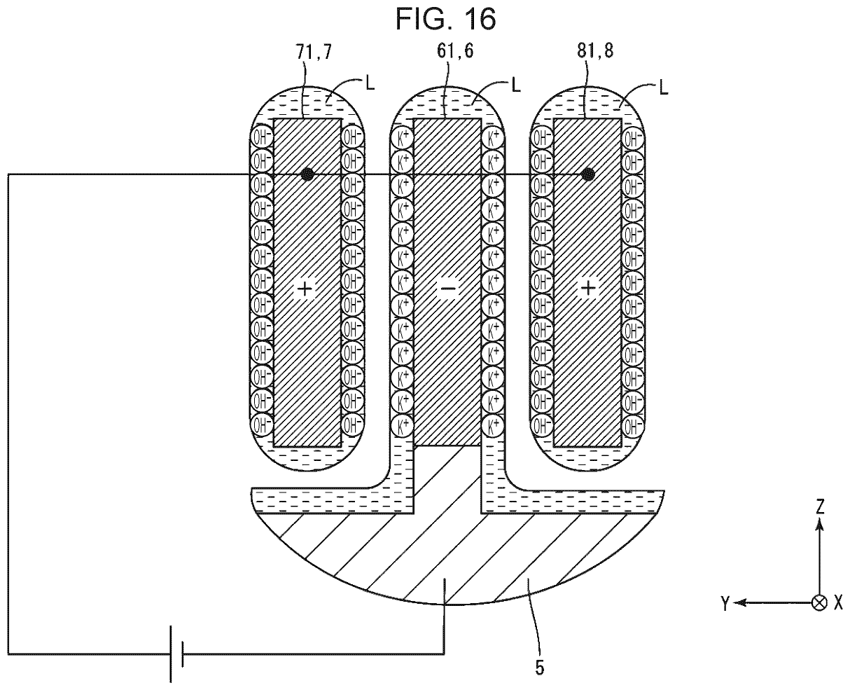

Next, the alkali ion solution L is supplied to a surface of the movable electrode 6 and surfaces of the first and second fixed electrodes 7 and 8 while maintaining a state in which a voltage is applied between the movable electrode 6 and the first and second fixed electrodes 7 and 8. There is no particular limitation on the alkali ion solution L, and for example, a KOH (potassium hydroxide) aqueous solution, a NaOH (sodium hydroxide) aqueous solution, or the like can be used. In the present embodiment, as illustrated in FIG. 14, the entire SOI substrate 2 is immersed in the alkali ion solution L to supply the alkali ion solution L to the surface of the movable electrode 6 and the surfaces of the first and second fixed electrodes 7 and 8. However, there is no particular limitation on the method for supplying the alkali ion solution L to the surface of the movable electrode 6 and the surfaces of the first and second fixed electrodes 7 and 8, and for example, spin coating, spray coating, or the like can be used.

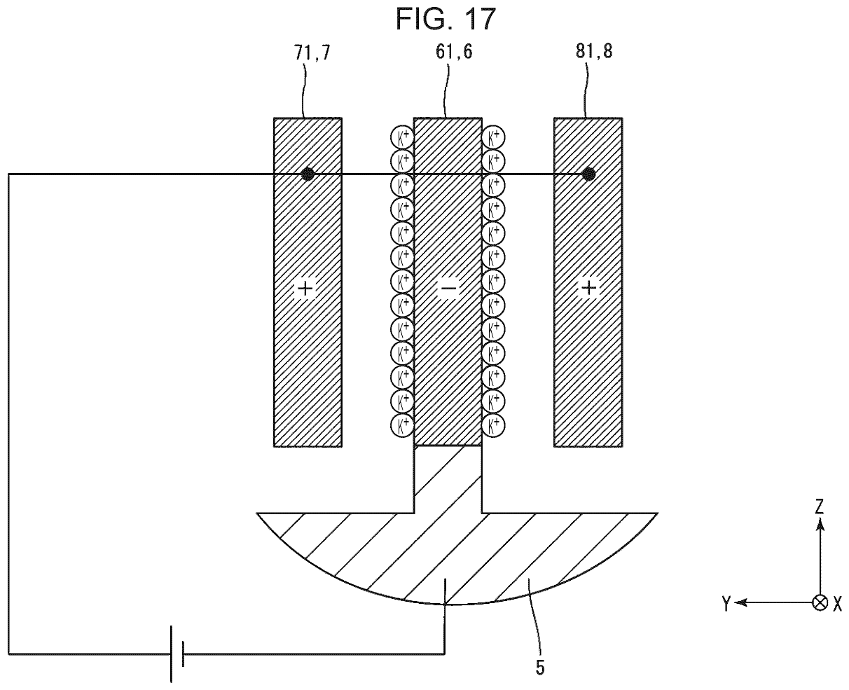

In this way, when the movable electrode 6 and the first and second fixed electrodes 7 and 8 are immersed in the alkali ion solution L while maintaining a state in which a voltage is applied between the movable electrode 6 and the first and second fixed electrodes 7 and 8, negatively charged hydroxide ions (OH⁻) are attracted to the positive electrodes, the first and second fixed electrodes 7 and 8, and conversely, positively charged alkaline ions are attracted to the negative electrode, the movable electrode 6, as illustrated in FIG. 15. Here, for ease of explanation, the alkaline ions are referred to as “K⁺”. Therefore, there are few alkaline ions and many hydroxide ions around the first and second fixed electrodes 7 and 8, and conversely, there are many alkaline ions and few hydroxide ions around the movable electrode 6.

Note that a voltage may be applied between the movable electrode 6 and the first and second fixed electrodes 7 and 8 after the movable electrode 6 and the first and second fixed electrodes 7 and 8 are immersed in the alkali ion solution L.

### Drying Step S52

In the drying step S52, the alkali ion solution L adhering to the movable electrode 6 and the first and second fixed electrodes 7 and 8 is dried. Specifically, first, as illustrated in FIG. 16, the movable electrode 6 and the first and second fixed electrodes 7 and 8 are taken out of the alkali ion solution L while maintaining a state in which a voltage is applied between the movable electrode 6 and the first and second fixed electrodes 7 and 8.

As described above, the movable electrode 6 and the first and second fixed electrodes 7 and 8 are taken out from the alkali ion solution L while maintaining a state in which a voltage is applied, many alkaline ions are present in the alkali ion solution L adhering to the surface of the movable electrode 6, and conversely, no alkaline ions are present in the alkali ion solution L adhering to the surfaces of the first and second fixed electrodes 7 and 8. An alkaline ion concentration difference can be easily created between the alkali ion solution L adhering to the surface of the movable electrode 6 and the alkali ion solution L adhering to the surfaces of the first and second fixed electrodes 7 and 8 by using the method of applying a voltage as described above.

Ideally, no alkaline ions are present in the alkali ion solution L adhering to the first and second fixed electrodes 7 and 8. However, depending on the applied voltage, the concentration of the alkali ion solution L, an immersion time, or the like, there may be a small amount of alkaline ions present in the alkali ion solution L adhering to the first and second fixed electrodes 7 and 8, in other words, there may be alkaline ions present in the alkali ion solution L adhering to the first and second fixed electrodes 7 and 8 at a concentration sufficiently lower than that of the movable electrode 6. For ease of explanation, in the present specification, the phrase “no alkali ions are present in the alkali ion solution L adhering to the first and second fixed electrodes 7 and 8” is used to include cases where a small amount of alkali ions are present in the alkali ion solution L adhering to the first and second fixed electrodes 7 and 8.

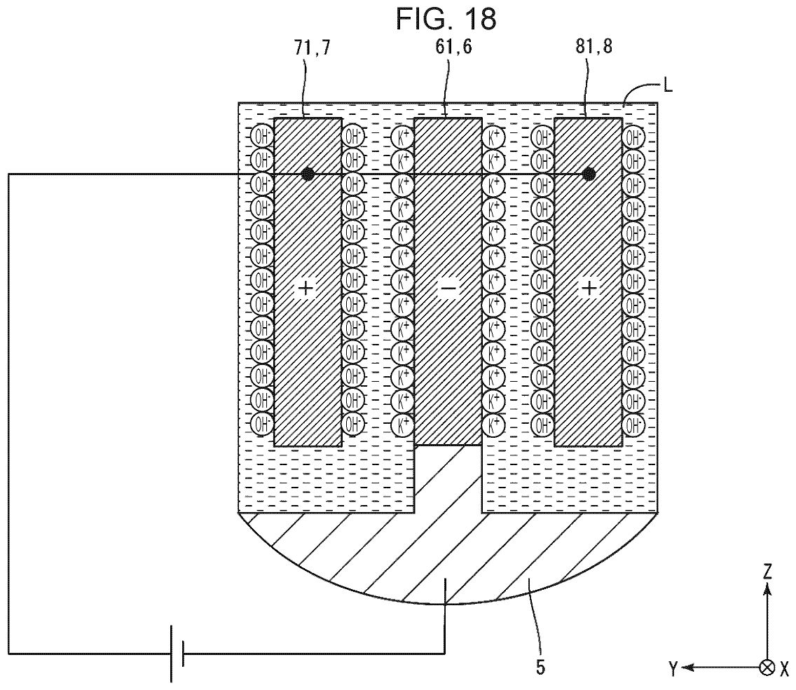

Next, the alkali ion solution L adhering to the movable electrode 6 and the first and second fixed electrodes 7 and 8 is dried. The drying method is not particularly limited, and may be natural drying or heating and drying using a heater or the like. By doing so, many alkali ions are fixed onto the surface of the movable electrode 6 as illustrated in FIG. 17. On the other hand, no alkali ions are fixed onto the surfaces of the first and second fixed electrodes 7 and 8.

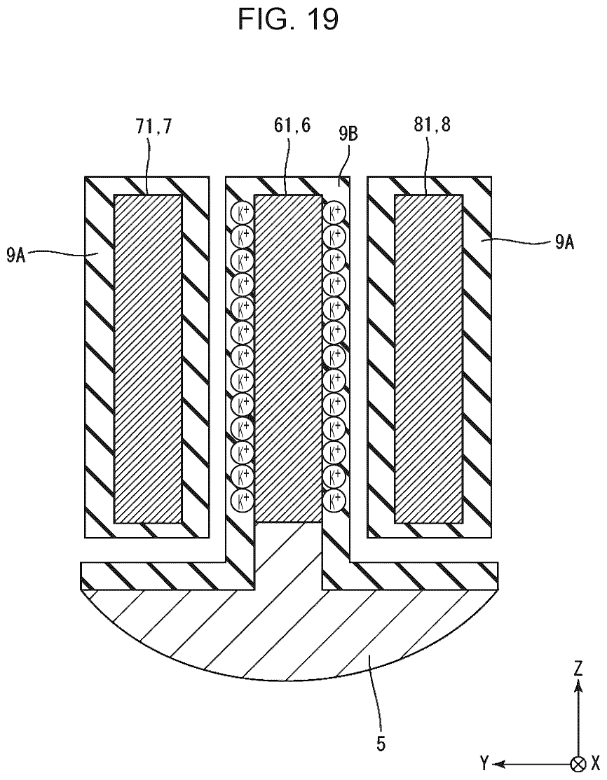

Here, the gap G between the movable electrode 6 and the first and second fixed electrodes 7 and 8 is narrow. Therefore, as illustrated in FIG. 18, a surface tension of the alkali ion solution L may cause the alkali ion solution L adhering to the surface of the movable electrode 6 and the alkali ion solution L adhering to the surfaces of the first and second fixed electrodes 7 and 8 to remain continuous without separating, which allow the alkali ions move within the continuous alkali ion solution L.

Therefore, the drying step S52 may be performed while maintaining a state in which a voltage is applied between the movable electrode 6 and the first and second fixed electrodes 7 and 8. As a result, it is possible to prevent movement of the alkali ions during a period from when the movable electrode 6 and the first and second fixed electrodes 7 and 8 are taken out from the alkali ion solution L to when the drying is completed. Therefore, it is possible to more reliably create a state in which many alkali ions are fixed onto the surface of the movable electrode 6 and no alkali ions are fixed onto the surfaces of the first and second fixed electrodes 7 and 8.

### Oxide Film Formation Step S53

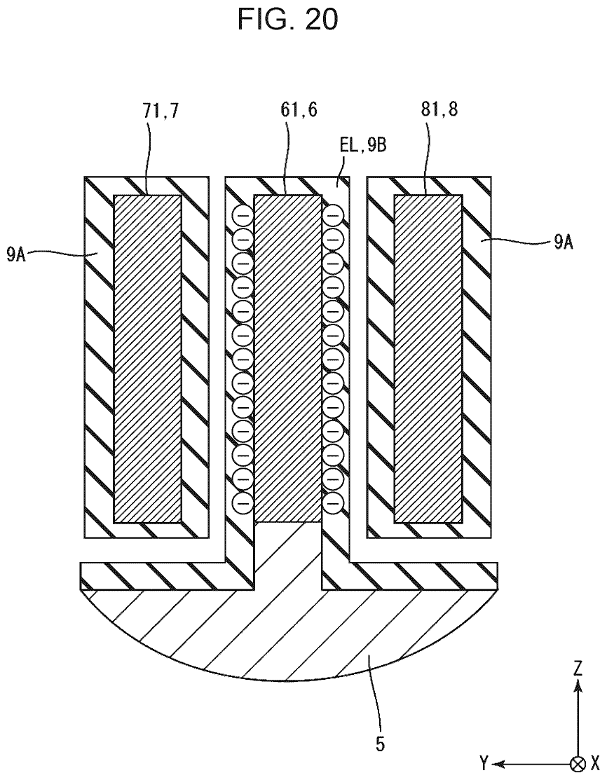

In the oxide film formation step S53, the first silicon layer 2A is thermally oxidized. In this embodiment, the SOI substrate 2 is put in a thermal oxidation furnace and heated in an oxygen atmosphere. As a result, as illustrated in FIG. 19, the second oxide film 9B, which is a silicon oxide film, is formed on the surface of the movable electrode 6, and the first oxide films 9A, which are silicon oxide films, are formed on the first and second fixed electrodes 7 and 8. The second oxide film 9B is an alkali-added oxide film that incorporates the alkali ions adhering to the surface of the movable electrode 6 in the drying step S52. The alkali ions in the second oxide film 9B are positively charged, but are paired with electrons of silicon atoms. Therefore, positive electric charges of the alkali ions and negative electric charges of the silicon atoms cancel each other out, resulting in electrical neutrality. Therefore, in this state, the second oxide film 9B is electrically neutral and has no surface potential.

### Charging Step S54

In the charging step S54, a voltage is applied to the movable electrode 6 to charge the second oxide film 9B, thereby forming the electret film EL. For example, the SOI substrate 2 is mounted on a positive electrode plate, and a voltage is applied between the positive electrode plate and a negative electrode terminal in a state in which the negative electrode terminal is in contact with a surface of the second oxide film 9B. Then, the positively charged alkali ions are attracted to the negative electrode terminal, which becomes a negative electrode, inside the second oxide film 9B and are combined with the electrons to lose the positive electric charges and become neutral. Then, as illustrated in FIG. 20, only the electrons paired with the alkali ions remain inside the second oxide film 9B as a result of losing the alkali ions. Since the electrons have negative electric charges, the second oxide film 9B becomes the electret film EL that is negatively charged and has a surface potential.

Here, as described above, in the vibration power generation device 1, the silicon oxide layer 2B is removed from between the movable electrode 6 and the movable portion 5, and thus, the movable electrode 6 and the movable portion 5 are electrically coupled to each other. Therefore, in the step S54, a voltage can be applied to the movable electrode 6 via the movable portion 5. Therefore, the step S54 can be easily performed.

In the charging step S54, a voltage may be applied only to the movable electrode 6 and not applied to the first and second fixed electrodes 7 and 8 as in the present embodiment. As described above, a small amount of alkaline ions may adhere to the surfaces of the first and second fixed electrodes 7 and 8. In this case, a small amount of alkaline ions are also present in the first oxide film 9A. Therefore, when a voltage is applied to the first and second fixed electrodes 7 and 8, the first oxide film 9A is slightly charged, and the charging may reduce a potential difference between the movable electrode 6 and the first and second fixed electrodes 7 and 8, which may reduce the power generation amount. Therefore, the power generation amount can be increased by not applying a voltage to the first and second fixed electrodes 7 and 8 and maintaining the first oxide film 9A in an electrically neutral state.

The vibration power generation device 1 is manufactured by performing the above-described steps. A difference in alkaline ion concentration can be easily created between the alkali ion solution L adhering to the surface of the movable electrode 6 and the alkali ion solution L adhering to the surfaces of the first and second fixed electrodes 7 and 8 by using such a manufacturing method. Therefore, even when the movable electrode 6 and the first and second fixed electrodes 7 and 8 mesh with each other, the electret film EL can be selectively formed only on the movable electrode 6 through a simple process.

Hereinabove, the method for manufacturing the vibration power generation device 1 has been described. As described above, such a manufacturing method includes the following steps: the first silicon layer patterning step S2 of patterning the first silicon layer 2A to form the first and second fixed electrodes 7 and 8, which are the first comb electrodes that move relatively, and the movable electrode 6, which is the second comb electrode aligned with the first and second fixed electrodes 7 and 8, the alkali ion solution supply step S51 of supplying the alkali ion solution L to the surfaces of the first and second fixed electrodes 7 and 8 and the surface of the movable electrode 6 in a state in which a voltage is applied between the first and second fixed electrodes 7 and 8 and the movable electrode 6 in such a way that the first and second fixed electrodes 7 and 8 have a higher potential than the movable electrode 6, the drying step S52 of drying the alkali ion solution L, the oxide film formation step S53 of forming the first oxide films 9A on the surfaces of the first and second fixed electrodes 7 and 8 and forming the second oxide film 9B on the surface of the movable electrode 6 by heating the first silicon layer 2A, and the charging step S54 of applying a voltage to the movable electrode 6 to charge the second oxide film 9B, thereby forming the electret film EL. A difference in alkaline ion concentration can be easily created between the alkali ion solution L adhering to the surface of the movable electrode 6 and the alkali ion solution L adhering to the surfaces of the first and second fixed electrodes 7 and 8 by using such a manufacturing method. Therefore, even when the movable electrode 6 and the first and second fixed electrodes 7 and 8 mesh with each other, the electret film EL can be selectively formed only on the movable electrode 6 through a simple process.

As described above, in the drying step S52, the alkali ion solution L is dried in a state in which a voltage is applied between the first and second fixed electrodes 7 and 8 and the movable electrode 6 in such a way that the first and second fixed electrodes 7 and 8 have a higher potential than the movable electrode 6. According to such a method, it is possible to more reliably create a state in which many alkali ions are fixed onto the surface of the movable electrode 6 and no alkali ions are fixed onto the surfaces of the first and second fixed electrodes 7 and 8.

As described above, in the charging step S54, no voltage is applied to the first and second fixed electrodes 7 and 8. Therefore, the first oxide film 9A can be maintained in an electrically neutral state, and the power generation amount can be increased.

As described above, in the first silicon layer patterning step S2, the first silicon layer 2A is patterned to form the first support portion 3A that supports one of the first and second fixed electrodes 7 and 8 and the movable electrode 6, in the present embodiment, supports the first and second fixed electrodes 7 and 8. Therefore, it is possible to couple the first and second fixed electrodes 7 and 8 and the support portion 3 to each other with a simple configuration.

As described above, the method for manufacturing the vibration power generation device 1 includes the preparation step S1 of preparing, before the first silicon layer patterning step S2, the SOI substrate 2 including the first silicon layer 2A, the second silicon layer 2C, and the silicon oxide layer 2B interposed between the first silicon layer 2A and the second silicon layer 2C, and the second silicon layer patterning step S3 of patterning the second silicon layer 2C to form the second support portion 3B that is integrated with the first support portion 3A to form the support portion 3, and the movable portion 5 that is movable relative to the second support portion 3B and supports the other of the first and second fixed electrodes 7 and 8 and the movable electrode 6, in the present embodiment, supports the movable electrode 6. With such a method, it is possible to achieve excellent dimensional accuracy and further reduce the size of the gap G between the movable electrode fingers 61 and the first and second fixed electrode fingers 71, 81. Therefore, it is possible to increase the capacitance between the movable electrode 6 and the first and second fixed electrodes 7 and 8.

As described above, the first and second fixed electrodes 7 and 8 are supported by the first support portion 3A, and the movable electrode 6 is supported by the movable portion 5. As described above, by forming the electret film EL on the movable electrode finger 61 that is displaced relative to the support portion 3, an electric charge generated during power generation can be taken out from the first and second fixed electrode fingers 71 and 81 that are fixed to the support portion 3. Therefore, it is easy to take out the electric charge.

As described above, in the step S1, the SOI substrate 2, in which the silicon oxide layer 2B is removed from between the movable electrode formation region Q6 as the second comb electrode formation region in which the movable electrode 6 of the first silicon layer 2A is formed, and the movable portion formation region Q5 in which the movable portion 5 of the second silicon layer 2C is formed, is prepared. By preparing such an SOI substrate 2, the movable electrode 6 electrically coupled to the second silicon layer 2C can be easily obtained. Therefore, in the charging step S54, a voltage can be applied to the movable electrode 6 via the second silicon layer 2C. Therefore, the charging step S54 can be easily performed.

As described above, in the first silicon layer patterning step S2 and the second silicon layer patterning step S3, the patterning is performed by dry etching. Therefore, it is possible to pattern the first silicon layer 2A and the second silicon layer 2C with high precision. Further, the through-hole with a high aspect ratio can be formed, so that the gap G between the movable electrode 6 and the first and second fixed electrodes 7 and 8 can be reduced in size. Therefore, the power generation amount can be further increased.

The method for manufacturing the vibration power generation device according to the present disclosure has been described above based on the illustrated embodiments, but the present disclosure is not limited thereto, and a configuration of each part can be replaced with any configuration having a similar function. Further, any other component or process may be added to the present disclosure.

What is claimed is:

1. A method for manufacturing a vibration power generation device, the method comprising:
a first silicon layer patterning step of patterning a first silicon layer to form a first comb electrode and a second comb electrode aligned with the first comb electrode;
an alkali ion solution supply step of supplying an alkali ion solution to a surface of the first comb electrode and a surface of the second comb electrode in a state in which a voltage is applied between the first comb electrode and the second comb electrode in such a way that the first comb electrode has a higher potential than the second comb electrode;
a drying step of drying the alkali ion solution;
an oxide film formation step of forming a first oxide film on the surface of the first comb electrode and forming a second oxide film on the surface of the second comb electrode by heating the first silicon layer; and
a charging step of applying a voltage to the second comb electrode to charge the second oxide film, thereby forming an electret film.

2. The method according to claim 1, wherein in the drying step, the alkali ion solution is dried in a state in which a voltage is applied between the first comb electrode and the second comb electrode in such a way that the first comb electrode has a higher potential than the second comb electrode.

3. The method according to claim 1, wherein in the charging step, no voltage is applied to the first comb electrode.

4. The method according to claim 1, wherein in the first silicon layer patterning step, the first silicon layer is patterned to form a first support portion that supports one of the first comb electrode and the second comb electrode.

5. The method according to claim 4, further comprising:
a preparation step of preparing, before the first silicon layer patterning step, a silicon on insulator (SOI) substrate including the first silicon layer, a second silicon layer, and a silicon oxide layer interposed between the first silicon layer and the second silicon layer; and
a second silicon layer patterning step of patterning the second silicon layer to form a second support portion that is integrated with the first support portion to form a support portion, and a movable portion that is configured to move relative to the second support portion and supports the other of the first comb electrode and the second comb electrode.

6. The method according to claim 5, wherein the first comb electrode is supported by the first support portion, and
the second comb electrode is supported by the movable portion.

7. The method according to claim 6, wherein in the preparation step, the SOI substrate, in which the silicon oxide layer is removed from between a second comb electrode formation region in which the second comb electrode of the first silicon layer is formed, and a movable portion formation region in which the movable portion of the second silicon layer is formed, is prepared.

8. The method according to claim 5, wherein in the first silicon layer patterning step and the second silicon layer patterning step, the patterning is performed by dry etching.
